(19) United States
(12) Patent Application Publication
(10) Pub. No.: US 2009/0218574 A1
(43) Pub. Date: Sep. 3, 2009

(54) Display device and manufacturing method therefor

(75) Inventors: Takeshi Noda, Mobara (JP); Toshio Miyazawa, Chiba (JP); Takuo Kaitoh, Mobara (JP); Daisuke Sonoda, Chiba (JP); Takeshi Kuriyagawa, Mobara (JP)

Correspondence Address: Juan Carlos A. Marquez;c/o Stites & Harbison PLLC, 1199 North Fairfax Street, Suite 900, Alexandria, VA, 22314-1437, US

(73) Assignee: Hitachi Displays, Ltd.

(21) Appl. No.: 12/379,095

(22) Filed: Feb. 12, 2009

(30) Foreign Application Priority Data
Feb. 29, 2008 (JP) 2008-049876

(51) Int. Cl. H01L 33/00

(52) U.S. Cl. 257/72; 438/34; 257/E33.003

(57) ABSTRACT

A display device includes a thin film transistor above a substrate, in which the thin film transistor is configured to include a gate electrode, a gate insulating film formed to cover the gate electrode, a semiconductor layer formed to stride over the gate electrode on the gate insulating film, an inter-layer insulating film formed to cover the semiconductor layer, and a pair of electrodes formed to be connected to each of sides of the semiconductor layer interposing the gate electrode therebetween through contact holes formed through the inter-layer insulating film, high concentration impurity layers are formed at each connecting portion of the electrodes of the semiconductor layer, and an annular low-concentration impurity layer is formed to surround at least one of the high concentration impurity layers.

### BACKGROUND OF THE INVENTION

The present invention relates to a display device and a manufacturing method therefore and particularly to a display device having a thin film transistor formed on a substrate and a manufacturing method therefor.

An active matrix type display device is configured such that in each of pixels arranged in a matrix, a scan signal is supplied to a signal line (gate signal line) common to each of pixels arranged in a row direction thereby to sequentially select the pixels in a column direction, and that a video signal is supplied through a signal line (drain signal line) common to each of pixels arranged in the column direction in accordance with the timing of the selection.

Therefore, a thin film transistor for taking in the video signal from the drain signal line into the pixel (pixel electrode) with the supply of the scan signal is provided in each of the pixels.

Further, a driving circuit for supplying a scan signal to the gate signal line and supplying a video signal to the drain signal line is provided on the substrate to which the pixels are formed. The driving circuit also includes a circuit having a plurality of thin film transistors.

Here, the thin film transistor is formed as a so-called MIS (Metal Insulator Semiconductor) type transistor including, for example, a gate insulating film formed to cover a gate electrode, a semiconductor layer formed to stride over the gate electrode on the upper surface of the gate insulating film, and a pair of electrodes (drain electrode and source electrode) arranged facing to each other interposing a region (channel region) above the gate electrode therebetween on the upper surface of the semiconductor layer.

A thin film transistor has been known in which a portion connected to each of the electrodes in the semiconductor layer includes a high-concentration impurity layer as a contact layer, and a low-concentration impurity layer having the same conductivity type is formed on the channel region side.

The low-concentration impurity layer is referred to as a so-called LDD (Lightly Doped Drain) layer, providing an effect of, for example, relaxing concentration of an electric field between the contact layer and the gate electrode.

A display device including such a thin film transistor has been disclosed in, for example, JP-A-10-96956.

### SUMMARY OF THE INVENTION

However, the thus configured thin film transistor requires a special step for forming the LDD layer, which inevitably increases the manufacturing man-hour.

The present inventors have found that the increase in the manufacturing man-hour is caused by the fact that the LDD layer is formed to the contact layer only on the channel region side and have attained a configuration which does not increase the manufacturing man-hour by forming the LDD layer into a new shape.

An object of the invention is to provide a display device including a thin film transistor having an LDD layer and with a configuration which does not increase the manufacturing man-hour.

Another object of the invention is to provide a method for manufacturing a display device including a thin film transistor having an LDD layer and in which the manufacturing man-hour is reduced.

An outline of a typical invention disclosed herein will be briefly described below.

(1) A display device according to the invention is, for example, a display device including a thin film transistor above a substrate, in which the thin film transistor is configured to include a gate electrode, a gate insulating film formed to cover the gate electrode, a semiconductor layer formed to stride over the gate electrode on the gate insulating film, an insulating film formed to cover the semiconductor layer, and a pair of electrodes formed to be connected to each of sides of the semiconductor layer interposing the gate electrode therebetween through contact holes formed through the insulating film, high-concentration impurity layers having a first conductivity type are formed at each connecting portion of the electrodes of the semiconductor layer, and an annular low-concentration impurity layer having the first conductivity type is formed to surround at least one of the high-concentration impurity layers with a region of the semiconductor layer at the periphery thereof.

(2) A display device according to the invention is, for example, a display device including a thin film transistor above a substrate, in which the thin film transistor is configured to include a gate electrode, a gate insulating film formed to cover the gate electrode, a semiconductor layer formed to stride over the gate electrode on the gate insulating film, an insulating film formed to cover the semiconductor layer, and a pair of electrodes formed to be connected to each of sides of the semiconductor layer interposing the gate electrode therebetween through contact holes formed through the insulating film, high-concentration impurity layers having a first conductivity type are formed at each connecting portion of the electrodes of the semiconductor layer, and an annular low-concentration impurity layer having the first conductivity type is formed to surround at least one of the high-concentration impurity layers without a region of the semiconductor layer on the side except for the channel region of the thin film transistor at the periphery thereof.

(3) A display device according to the invention is, for example, a display device including a thin film transistor above a substrate, in which the thin film transistor is configured to include a gate electrode, a gate insulating film formed to cover the gate electrode, a semiconductor layer formed to stride over the gate electrode on the gate insulating film, an insulating film formed to cover the semiconductor layer, and a pair of electrodes formed to be connected to each of sides of the semiconductor layer interposing the gate electrode therebetween through contact holes formed through the insulating film, high-concentration impurity layers having a first conductivity type are formed at each connecting portion of the electrodes of the semiconductor layer, an annular low-concentration impurity layer having the first conductivity type is formed to surround at least one of the high-concentration impurity layers with a region of the semiconductor layer at the periphery thereof, and the low-concentration impurity layer is connected with the electrode in the entire area.

(4) A display device according to the invention is, for example, a display device including a thin film transistor above a substrate, in which the thin film transistor is configured to include a gate electrode, a gate insulating film formed to cover the gate electrode, a semiconductor layer formed to stride over the gate electrode on the gate insulating film, an insulating film formed to cover the semiconductor layer, and a pair of electrodes formed to be connected to each of sides of the semiconductor layer interposing the gate electrode therebetween through contact holes formed through the insulating film, high-concentration impurity layers having a first conductivity type are formed at each connecting portion of the electrodes of the semiconductor layer, an annular low-concentration impurity layer having the first conductivity type is formed to surround at least one of the high-concentration impurity layers with a region of the semiconductor layer at the periphery thereof, and the low-concentration impurity layer is connected with the electrode in other portion than the portion on the channel region side of the thin film transistor.

(5) In a display device according to the invention, based on any of the configurations of (1) to (4), the semiconductor layer is a polycrystalline semiconductor layer. The polycrystalline semiconductor layer is, for example, a polysilicon layer.

(6) A method for manufacturing a display device according to the invention includes, for example, the steps of forming, above a substrate, a gate electrode, a gate insulating film formed to cover the gate electrode, a semiconductor layer formed to stride over the gate electrode on the gate insulating film, and an inter-layer insulating film formed to cover the semiconductor layer, forming a resist film having an opening at a predetermined portion on the inter-layer insulating film, forming a contact hole exposing a part of the semiconductor layer through the inter-layer insulating film by etching using the resist film as a mask, making the opening of the resist film larger than the contact hole, implanting a high-concentration impurity into the semiconductor layer through the contact hole, implanting a low-concentration impurity having the same conductivity type as the high-concentration impurity through the inter-layer insulating film around the contact hole, and removing the resist film to form an electrode connected to the semiconductor layer through the contact hole.

(7) In a method for manufacturing a display device according to the invention, for example, based on the configuration of (6), the step of making the opening of the resist film larger than the contact hole includes the step of drawing back the resist film around the opening by ashing.

(8) In a method for manufacturing a display device according to the invention, for example, based on the configuration of (6), the resist film has a region around the opening whose thickness is less than that of the resist film in other region, and the step of making the opening of the resist film larger than the contact hole includes the step of removing the region of the resist film whose thickness is less than that of the resist film in other region.

(9) A method for manufacturing a display device according to the invention includes, for example, the steps of forming, above a substrate, a gate electrode, a gate insulating film formed to cover the gate electrode, a semiconductor layer formed to stride over the gate electrode on the gate insulating film, and an inter-layer insulating film formed to cover the semiconductor layer, forming a resist film having an opening at a predetermined portion on the inter-layer insulating film, forming a contact hole exposing a part of the semiconductor layer larger than the opening of the resist film through the inter-layer insulating film by etching using the resist film as a mask, implanting a high-concentration impurity into the semiconductor layer through the opening of the resist film, removing the resist film and implanting a low-concentration impurity having the same conductivity type as the high-concentration impurity into the semiconductor layer through the contact hole, and forming an electrode connected to the semiconductor layer through the contact hole.

(10) In a method for manufacturing a display device according to the invention, based on any of the configurations of (6) to (9), the semiconductor layer is a polycrystalline semiconductor layer formed of, for example, polysilicon.

The invention is not restricted to the above configurations and can be changed in various ways without departing from the technical idea of the invention.

The display device according to the invention can provide the configuration which does not increase the manufacturing man-hour even when the display device includes a thin film transistor having an LDD layer.

The method for manufacturing a display device according to the invention can reduce the manufacturing man-hour even when the display device includes a thin film transistor having an LDD layer.

### BRIEF DESCRIPTION OF THE DRAWINGS

FIGS. 1A and 1B are plan views showing a configuration of an embodiment of a pixel of a display device according to the invention;

FIG. 2 is a cross sectional view along the line II-II in FIG. 1B;

FIGS. 3A through 3K are step views showing an embodiment of a manufacturing method of the display device shown in FIG. 1, showing steps in the forming region of a thin film transistor;

FIGS. 4A and 4B are configuration views showing a configuration of another embodiment of a pixel of a display device according to the invention;

FIGS. 5A through 5J are step views showing an embodiment of a manufacturing method of the display device shown in FIGS. 4A and 4B, illustrating steps in the forming region of a thin film transistor;

FIGS. 6A and 6B are configuration views showing a configuration of still another embodiment of a pixel of a display device according to the invention;

FIGS. 7A through 7K are step views showing an embodiment of a manufacturing method of the display device shown in FIGS. 6A and 6B, illustrating steps in the forming region of a thin film transistor; and

FIGS. 8A and 8B are configuration views showing a configuration of yet another embodiment of a pixel of a display device according to the invention.

### DESCRIPTION OF THE PREFERRED EMBODIMENTS

Hereinafter, embodiments of a display device according to the invention will be described using the drawings.

### Embodiment 1

### (Configuration of Pixel)

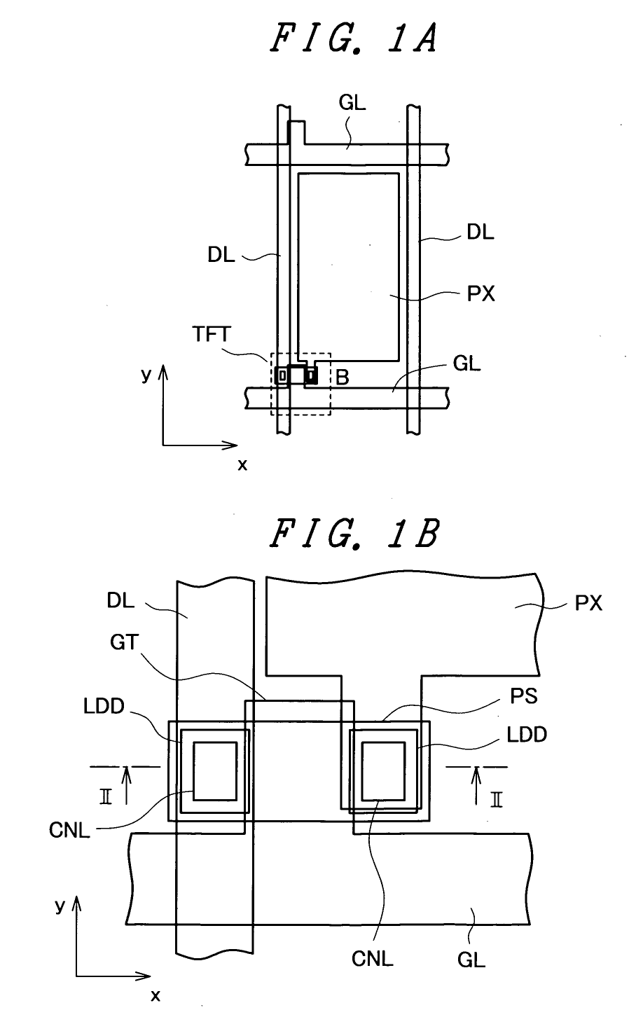

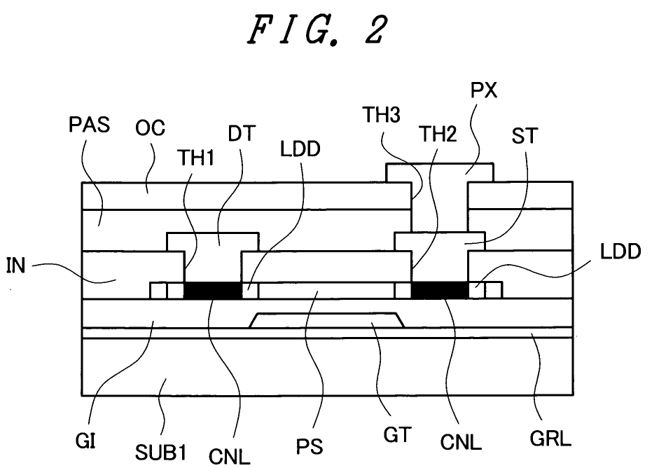

FIG. 1A is a schematic plan view showing an embodiment of a pixel of a display device according to the invention, while FIG. 1B shows an enlarged view of a portion shown by the dashed line frame B in FIG. 1A. FIG. 2 shows a cross sectional view along the line II-II in FIG. 1B.

FIG. 1A shows an embodiment of a pixel in a liquid crystal display device, showing a configuration of a pixel formed to a surface (main surface) on the liquid crystal side of one substrate SUB1 of a pair of substrates arranged facing to each other via liquid crystal.

In FIG. 1A, gate signal lines GL extending in the x direction in the drawing and arranged in parallel in the y direction are formed on the upper surface of an underlayer GRL (refer to FIG. 2) formed on the main surface of the substrate SUB1 (refer to FIG. 2).

The gate signal lines GL form a rectangular region together with drain signal lines DL described later, and the region serves as a pixel region.

The gate signal line GL is formed with a gate electrode GT protruding to the pixel region side at, for example, a part thereof. The gate electrode GT is formed as a gate electrode of a thin film transistor TFT described later.

An insulating film GI (refer to FIG. 2) is formed to cover the gate signal line GL on the upper surface of the substrate SUB1. The gate insulating film GI functions as a gate insulating film in the forming region of the thin film transistor TFT.

On the surface of the insulating film GI, a semiconductor layer PS formed of an island-shaped intrinsic semiconductor layer in which, for example, amorphous Si (noncrystalline semiconductor) is converted to poly-Si (polycrystalline semiconductor) with laser irradiation or an ultra-low concentration semiconductor layer including a small amount of impurity necessary for controlling a threshold value is formed. The semiconductor layer PS is arranged crossing the gate electrode GT so as to stride over the gate electrode GT.

In addition, the semiconductor layer PS is formed with a contact layer CNL doped with a high-concentration n (+) type impurity and an annular LDD (Lightly Doped Drain) layer LDD doped with a low concentration n (−) type impurity so as to surround the contact layer CNL at the periphery of the contact layer at each portion positioned on both sides with respect to the gate electrode GT.

The LDD layer LDD is formed in the forming region of the semiconductor layer PS. Accordingly, the periphery of the semiconductor layer PS is formed as the intrinsic semiconductor layer or the ultra-low concentration semiconductor layer. In other words, The LDD layer LDD is formed to include a region of the intrinsic semiconductor layer or the ultra-low concentration semiconductor layer at the periphery thereof.

On the upper surface of the substrate SUB1, an inter-layer insulating film IN is formed to cover the semiconductor layer PS. The drain signal lines DL and a source electrode ST are formed on the upper surface of the inter-layer insulating film IN.

The drain signal lines DL are formed extending in the y direction in the drawing and arranged in parallel in the x direction, forming the rectangular pixel region together with the gate signal lines GL as described above.

The drain signal line DL is connected to the contact layer CNL at a part thereof through a contact hole TH1 which is formed through the inter-layer insulating film IN and exposes the contact layer CNL of the semiconductor layer PS on one side.

The portion of the drain signal line DL connected to the contact layer CNL functions as a drain electrode DT of the thin film transistor TFT.

The source electrode ST is connected to the contact layer CNL through a contact hole TH2 which is formed through the inter-layer insulating film IN and exposes the contact layer CNL of the semiconductor layer PS on the other side.

On the upper surface of the substrate SUB1, a protection film PAS is formed to cover the drain signal line DL and the source electrode ST, and further a planarization film OC made of, for example, a resin material is successively formed thereon.

On the upper surface of the planarization film OC, pixel electrodes PX made of, for example, ITO (Indium Tin Oxide) are formed over substantially the entire pixel region. The pixel electrode PX is formed on the source electrode ST through a contact hole TH3 formed through the planarization film OC and the protection film PAS.

The pixel electrode PX is caused to generate an electric field between the pixel electrode PX and a counter electrode made of a transparent film such as of ITO formed to the surface on the liquid crystal side of another substrate which is arranged facing to the substrate SUB1 via liquid crystal and drives the liquid crystal with the electric field.

A pixel to which the invention is applied is not limited to the above-described one. For example, the pixel may be of a so-called IPS (In Plane Switching) type in which a plurality of linear pixel electrodes are arranged to overlap a counter electrode made of a transparent conductive film via an insulating film above the substrate SUB1.

### (Manufacturing Method)

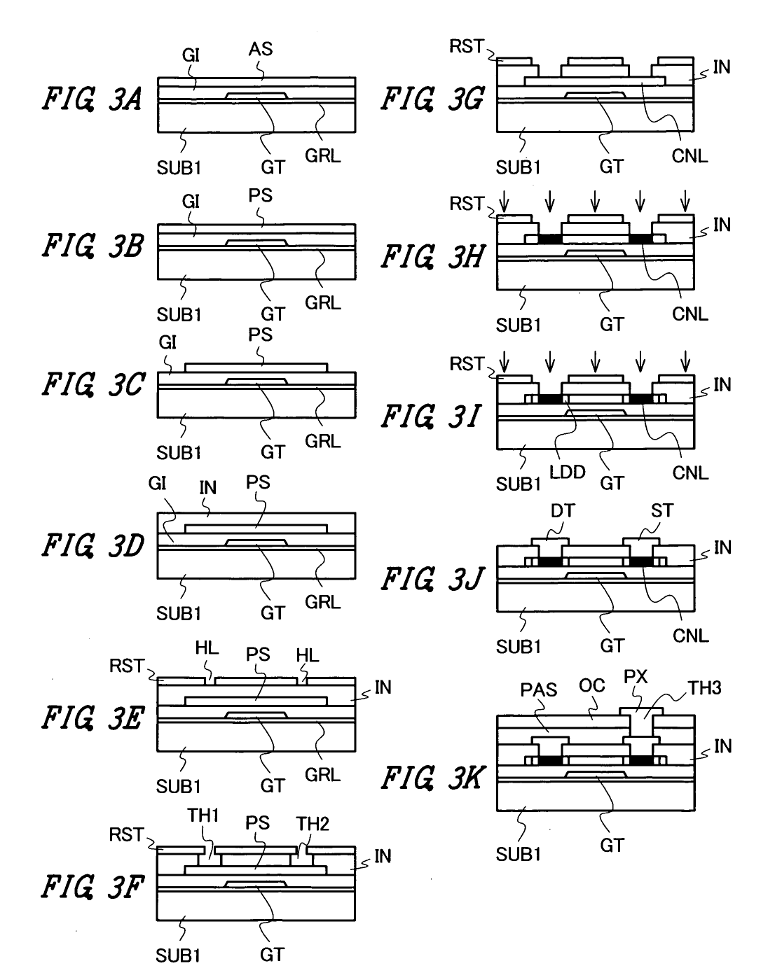

FIGS. 3A through 3K are step views showing an embodiment of a manufacturing method for a display device according to the invention, showing the manufacturing steps in the portion shown in FIG. 2.

Hereinafter, descriptions will be made in the order of the steps.

### Step 1. (FIG. 3A)

The substrate SUB1 made of, for example, glass is prepared, and the underlayer GRL made of a silicon nitride film is formed by CVD (Chemical Vapor Deposition) on the surface of the substrate SUB1 on the liquid crystal side. The underlayer GRL is formed in order to avoid the intrusion of impurities in the substrate SUB1 into the semiconductor layer PS of the thin film transistor TFT described later.

Then, the gate electrode GT is formed on the upper surface of the underlayer GRL. The gate electrode GT is formed of a high-melting-point metal such as Mo or W. This is because the semiconductor layer of the thin film transistor TFT is formed by crystallizing amorphous Si and thereby exposed to a high temperature at the time as will be described later.

On the upper surface of the substrate SUB1, the insulating film GI made of a silicon oxide film or a silicon nitride film is formed to cover the gate electrode GT by, for example, the CVD, and further a semiconductor layer AS made of amorphous Si is formed thereon.

### Step 2. (FIG. 3B)

The semiconductor layer AS is subjected to a dehydrogenation treatment and irradiated with excimer laser, thereby being converted into the polycyrstal semiconductor layer PS made of poly-Si.

### Step 3. (FIG. 3C)

By etching the semiconductor layer PS by a photolithographic technique, the semiconductor layer PS is left in the forming region of the thin film transistor TFT, while being removed in other regions.

### Step 4. (FIG. 3D)

On the upper surface of the substrate SUB1, the inter-layer insulating film IN made of, for example, a silicon oxide film is formed to cover the semiconductor layer PS by, for example, the CVD.

Since the inter-layer insulating film IN acts as a capacitor between the gate signal line GL and the drain signal line DL and further as a through film upon implanting an impurity as will be apparent later, the thickness is set to, for example, 200 nm or less in view of them.

Then, an impurity is implanted into the semiconductor layer PS in order to control the Vth of the thin film transistor TFT.

### Step 5. (FIG. 3E)

A resist film RST is formed on the upper surface of the inter-layer insulating film IN, and holes HL are formed through the resist film RST through exposing and developing steps.

The holes HL of the resist film RST are formed at portions corresponding to the connecting portions of the drain electrode and the source electrode of the thin film transistor TFT with the semiconductor layer PS.

### Step 6. (FIG. 3F)

The inter-layer insulating film IN is etched using the resist film RST as a mask to form the contact holes TH1 and TH2 through the inter-layer insulating film IN. The formation of the contact holes TH1 and TH2 is conducted until the surface of the semiconductor layer PS is exposed.

### Step 7. (FIG. 3G)

The resist film RST is subjected to an ashing treatment. The ashing treatment of the resist film RST is conducted in order to draw back side wall surface of the resist film RST from side wall surface of the contact holes TH1 and TH2 formed through the inter-layer insulating film IN such that the hole HL of the resist film RST becomes larger.

In this case, the region between the side wall surface of the contact holes TH1 and TH2 and the side wall surface of the hole HL corresponds to the length of the LDD layer which is formed in the semiconductor layer PS later.

The hole HL of the resist film RST and the contact hole TH1 or TH2 of the inter-layer insulating film IN are formed concentrically to each other with no misalignment, which provides an effect that the LDD layer does not vary in length.

### Step 8. (FIG. 3H)

A high-concentration n (+) type impurity including, for example, phosphorus (P) is ion-implanted using the resist film RST as a mask. In this case, the peak position of the ion implantation is set so as to be positioned within the semiconductor layer PS in the portion where the semiconductor layer PS is exposed due to the contact holes TH1 and TH2 and within the inter-layer insulating film IN in the region where the inter-layer insulating film IN is present.

The n (+) type impurity is implanted into the semiconductor layer PS through the contact holes TH1 and TH2 in the regions where the contact holes TH1 and TH2 are formed. This forms the contact layers CNL in the semiconductor layer PS.

In the region where the contact holes TH1 and TH2 are not formed, most of the n (+) type impurities remain in the inter-layer insulating film IN.

### Step 9. (FIG. 3I)

A low-concentration n (−) type impurity including phosphorus (P) is ion-implanted using the resist film RST as a mask. In this case, the peak position of the ion implantation is set within the semiconductor layer PS in the portion where ions are implanted using the inter-layer insulating film as a through film, that is, the regions where the holes HL of the resist film RST are formed but the contact holes TH1 and TH2 are not formed.

The n (−) type impurity is implanted into the semiconductor layer PS in the regions where the holes HL of the resist film RST are formed but the contact holes TH1 and TH2 are not formed. This forms the LDD layers LDD in the semiconductor layer PS.

In the regions where the contact holes TH1 and TH2 are formed, the peak position of the n (−) type impurity is set within the insulating film GI.

Thereafter, annealing is conducted for activating the impurity implanted into the semiconductor layer PS.

### Step 10. (FIG. 3J)

On the upper surface of the substrate SUB1, a metal layer made of aluminum (Al) is formed and etched by the photolithographic technique, whereby the drain electrode DT connected to the semiconductor layer PS (contact layer CNL) through one contact hole TH1 formed through the inter-layer insulating film IN and the source electrode ST connected to the semiconductor layer PS (contact layer CNL) through the other contact hole TH2 are formed.

### Step 11. (FIG. 3K)

On the upper surface of the substrate SUB1, the protection film PAS made of, for example, a silicon nitride film and the planarization film OC made of, for example, a resin film are successively formed, and a contact hole TH3 which exposes a part of the source electrode ST is formed through the planarization film OC and the protection film PAS.

On the upper surface of the planarization film OC, the pixel electrode PX made of, for example, a transparent conductive film of ITO is formed. A part of the pixel electrode PX is connected to the source electrode ST through the contact hole TH3.

### Embodiment 2

### (Configuration of Pixel)

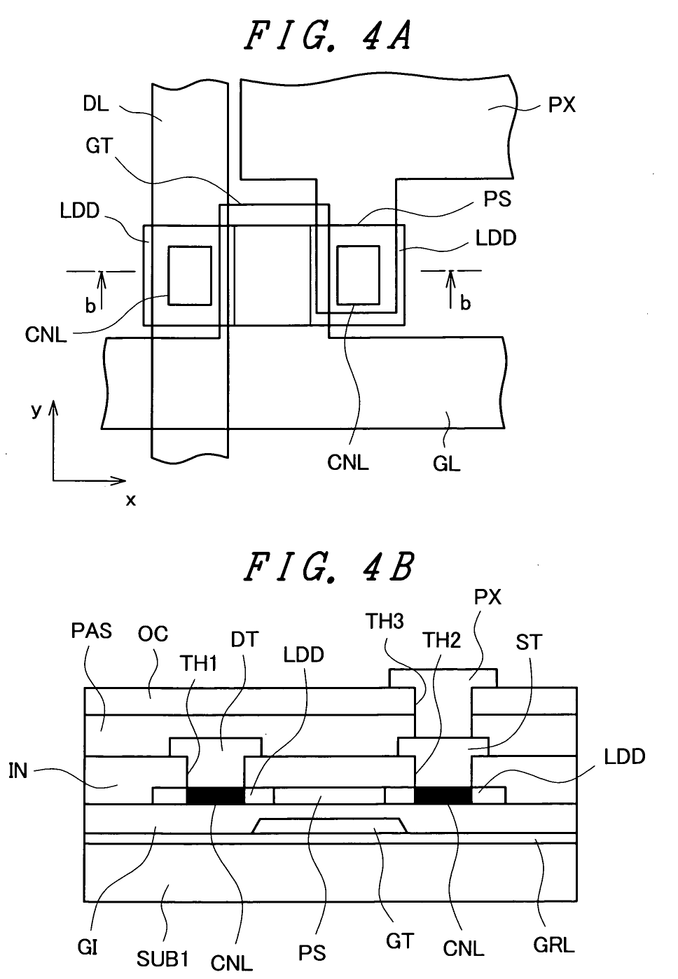

FIG. 4A is a schematic plan view showing another embodiment of a pixel of a display device according to the invention, corresponding to FIG. 1B.

FIG. 4B is a cross sectional view along the line b-b in FIG. 4A, corresponding to FIG. 2.

The configuration of FIG. 4A is different from that of FIG. 1B in LDD layers LDD formed in a semiconductor layer PS of a thin film transistor TFT.

That is, the annular LDD layer LDD formed to surround the periphery of a contact layer CNL at both ends of the semiconductor layer PS forms the outline of the semiconductor layer PS with any three sides thereof except for the side on the channel region side.

In other words, the intrinsic semiconductor layer or the ultra-low concentration semiconductor layer in the semiconductor layer PS is not formed on the sides of the LDD layer LDD except for the channel region side.

The thus configured thin film transistor TFT can avoid the problem that off current is increased due to electrons and holes generated in a depletion layer when light is irradiated to the depletion layer in the vicinity of the intrinsic semiconductor layer or the ultra-low concentration semiconductor layer in the case where the intrinsic semiconductor layer or the ultra-low concentration semiconductor layer is formed to surround the LDD layer LDD.

### (Manufacturing Method)

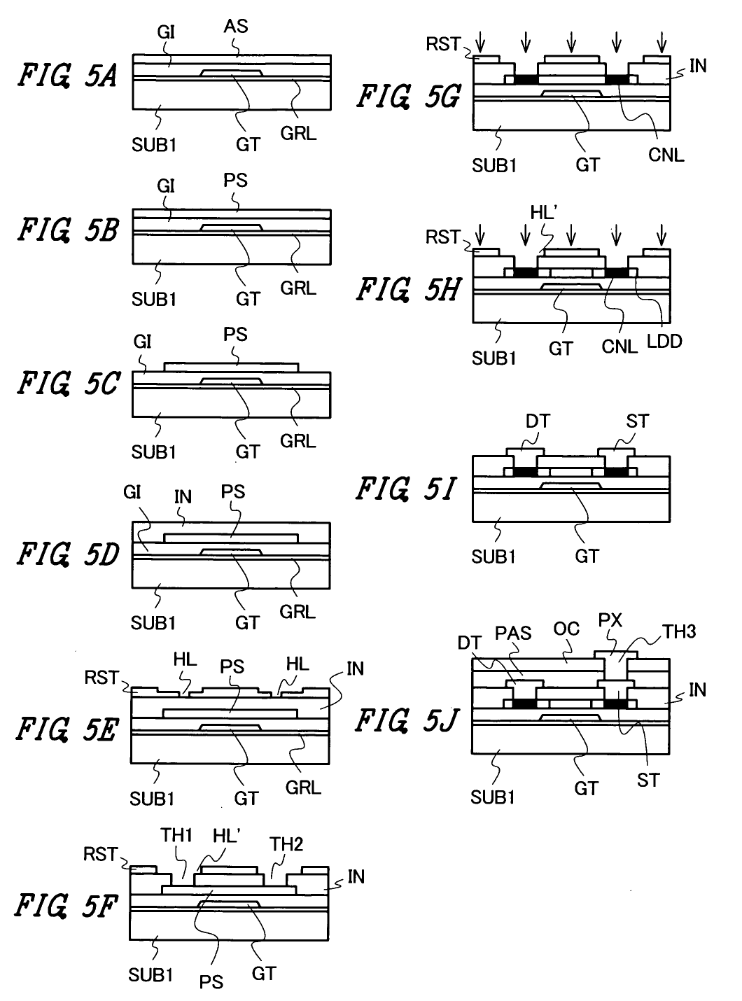

FIGS. 5A through 5J are configuration views showing an embodiment of a manufacturing method for a display device having the thin film transistor TFT shown in FIGS. 4A and 4B, showing the steps in the portion of the thin film transistor TFT. FIGS. 5A through 5J correspond to FIGS. 3A through 3K.

FIGS. 5A through 5D are similar to the steps of FIGS. 3A through 3D. Therefore, the steps of FIG. 5E and later figures will be described in the following description.

### Step 1. (FIG. 5E)

A resist film RST is formed on the upper surface of an inter-layer insulating film IN. By using a so-called half exposure technique, holes HL are formed through the resist film RST and portions where the thickness of the resist film RST is reduced by one step are formed around the holes HL.

The portion of the hole TH of the resist film RST corresponds to the forming region of a contact layer of the semiconductor layer PS connected to the drain electrode DT and the source electrode ST both described later, while the portion where the thickness is reduced by one step corresponds to the forming region of an LDD layer. Further, the portion where the resist film RST is formed to be the thickest is a region functioning as a mask against an impurity when the impurity is implanted in the later step.

### Step 2. (FIG. 5F)

The inter-layer insulating film IN is selectively etched using the resist film RST as a mask, whereby contact holes TH1 and TH2 are formed through the inter-layer insulating film IN to expose a part of the semiconductor layer PS.

Next, the resist film RST is subjected to ashing over the entire surface to expose the surface of the inter-layer insulating film IN in the portions where the thickness is reduced by one step in the previous step, that is, around the contact holes TH1 and TH2. This makes the holes HL formed through the photoresist film RST holes HL′ larger than the holes HL.

The resist film RST is left on the inter-layer insulating film IN at the portion where the film is formed to be the thickest in the previous step.

### Step 3. (FIG. 5G)

A high-concentration n (+) type impurity including, for example, phosphorus (P) is ion-implanted using the resist film RST as a mask. In this case, the peak position of the ion implantation is set so as to be positioned within the semiconductor layer PS in the portion where the semiconductor layer PS is exposed due to the contact holes TH1 and TH2 and within the inter-layer insulating film IN in the region where the inter-layer insulating film IN is present.

The n (+) type impurity is implanted into the semiconductor layer PS through the contact holes TH1 and TH2 in the regions where the contact holes TH1 and TH2 are formed.

In the region where the contact holes TH1 and TH2 are not formed, most of the n (+) type impurities remain in the inter-layer insulating film IN.

### Step 4. (FIG. 5H)

A low-concentration n (−) type impurity including phosphorus (P) is ion-implanted using the resist film RST as a mask. In this case, the peak position of the ion implantation is set within the semiconductor layer PS in the portion where ions are implanted using the inter-layer insulating film IN as a through film, that is, the regions where the holes HL′ of the resist film RST are formed but the contact holes TH1 and TH2 are not formed.

The n (−) type impurity is implanted into the semiconductor layer PS in the regions where the holes HL′ of the resist film RST are formed but the contact holes TH1 and TH2 are not formed.

In the region of the inter-layer insulating film IN where the contact holes TH1 and TH2 are formed, the peak position of the n (−) type impurity is within the insulating film GI.

Thereafter, annealing is conducted for activating the impurity implanted into the semiconductor layer PS.

The subsequent steps of FIGS. 5I and 5J are similar to the steps shown in FIGS. 3I and 3J, where the formation of a drain electrode DT and a source electrode ST, and further the formation of a protection film PAS, a planarization film OC, a contact hole TH3, and a pixel electrode PX are conducted.

### Embodiment 3

### (Configuration of Pixel)

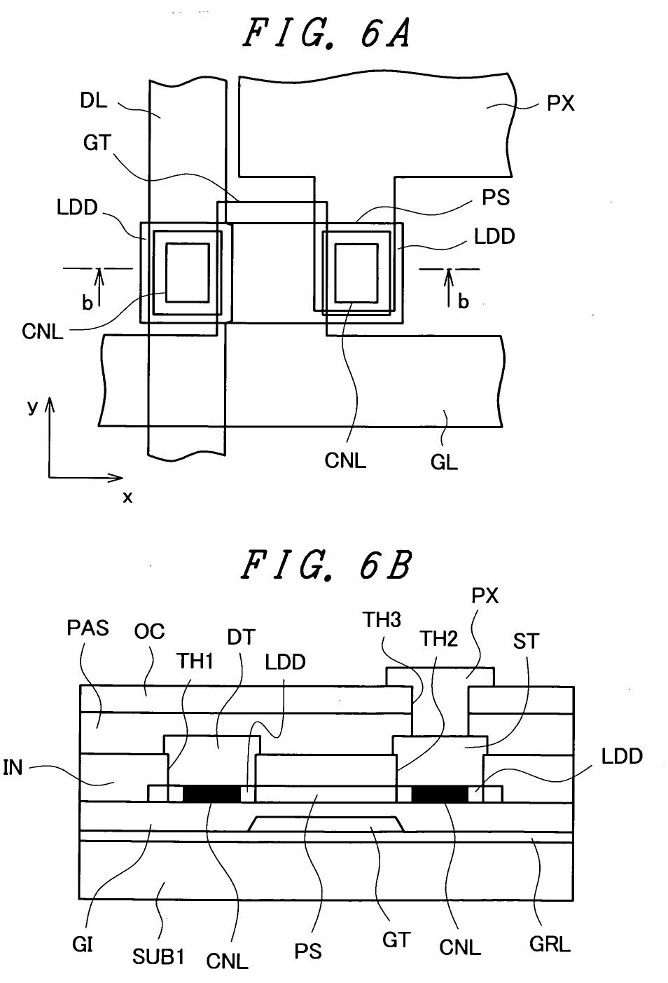

FIG. 6A is a schematic plan view showing still another embodiment of a pixel of a display device according to the invention, corresponding to FIG. 1B.

FIG. 6B is a cross sectional view along the line b-b in FIG. 6A, corresponding to FIG. 2.

The configuration of FIG. 6A is different from that of FIG. 1B in that a drain electrode DT of a thin film transistor TFT is electrically connected not only to a contact layer CNL of a semiconductor layer PS but also to an LDD layer LDD around the contact layer CNL, and that a source electrode ST is electrically connected not only to a contact layer CNL of the semiconductor layer PS but also to an LDD layer LDD around the contact layer CNL.

That is, both of contact holes TH1 and TH2 of an inter-layer insulating film IN are formed so as to expose the contact layer CNL and the LDD layer LDD, the drain electrode DT (drain signal line DL) is formed so as to sufficiently cover the contact hole TH1, and the source electrode ST is formed so as to sufficiently cover the contact hole TH2.

The thus configured thin film transistor provides an effect that the thickness of the inter-layer insulating film IN can be set to be great since the inter-layer insulating film IN is not used as a through film when an impurity is implanted. This can make a capacitor small between a gate signal line GL and, for example, a drain signal line DL on the inter-layer insulating film IN.

### (Manufacturing Method)

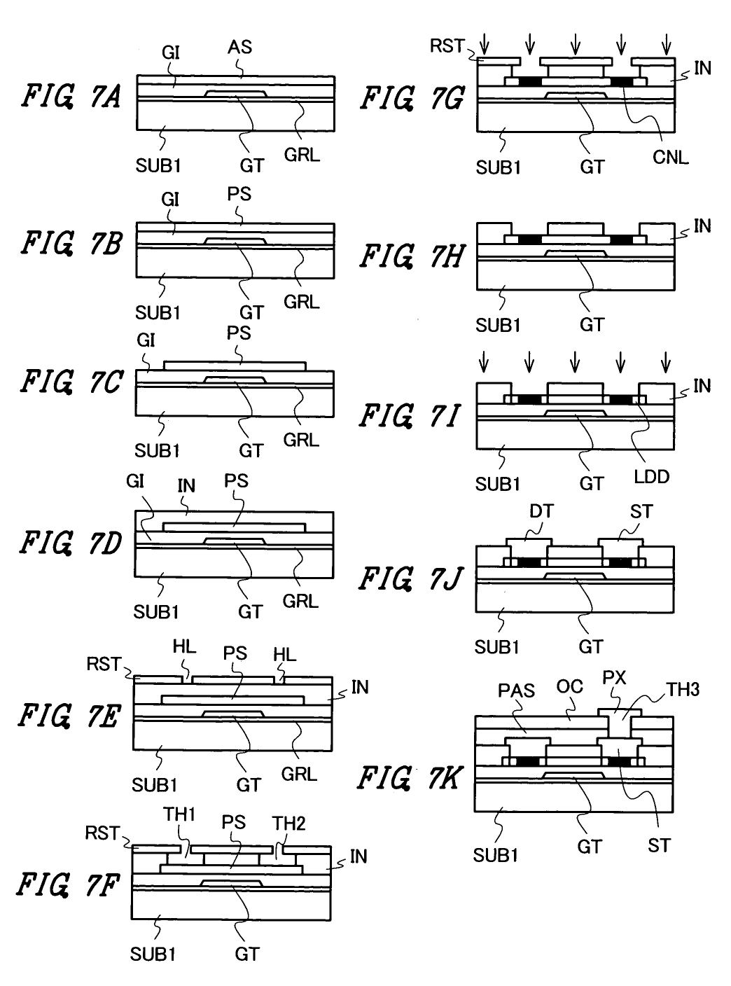

FIGS. 7A through 7K are configuration views showing an embodiment of a manufacturing method for a display device having the thin film transistor TFT shown in FIGS. 6A and 6B, showing the steps in the portion of the thin film transistor TFT. FIGS. 7A through 7K correspond to FIGS. 3A through 3K.

FIGS. 7A through 7E are similar to the steps of FIGS. 3A through 3E. Therefore, the steps of FIG. 7F and later figures will be described in the following description.

### Step 1. (FIG. 7F)

The inter-layer insulating film IN is etched using the resist film RST through which the holes HL are formed in the previous step (FIG. 7E) as a mask, whereby contact holes TH1 and TH2 are formed through the inter-layer insulating film IN to expose a part of the semiconductor layer PS.

In this case, the etching is performed such that the inter-layer insulating film IN is side-etched, whereby the contact holes TH1 and TH2 are made sufficiently larger than the holes HL of the resist film RST.

### Step 2. (FIG. 7G)

A high-concentration n (+) type impurity including, for example, phosphorus (P) is ion-implanted using the resist film RST as a mask. In this case, the peak position of the ion implantation is set so as to be positioned within the semiconductor layer PS.

The n (+) type impurity is implanted into the semiconductor layer PS through the contact holes TH1 and TH2 in the regions where the holes HL of the resist film RST are formed.

That is, the n (+) type impurity is implanted into the regions where the holes HL of the resist film RST are formed in the portions of the semiconductor layer PS exposed due to the contact holes TH1 and TH2.

### Step 3. (FIG. 7H)

The resist film RST is removed.

### Step 4. (FIG. 7I)

A low-concentration n (−) type impurity, for example, including phosphorus (P) is ion-implanted. In this case, the peak position of the ion implantation is set so as to be positioned within the semiconductor layer PS.

Therefore, the n (−) type impurity is implanted into the semiconductor layer PS in the regions where the contact holes TH1 and TH2 are formed to form the LDD layers around the contact layers.

The subsequent steps of FIGS. 7J and 7K are similar to the steps shown in FIGS. 3J and 3K.

### Embodiment 4

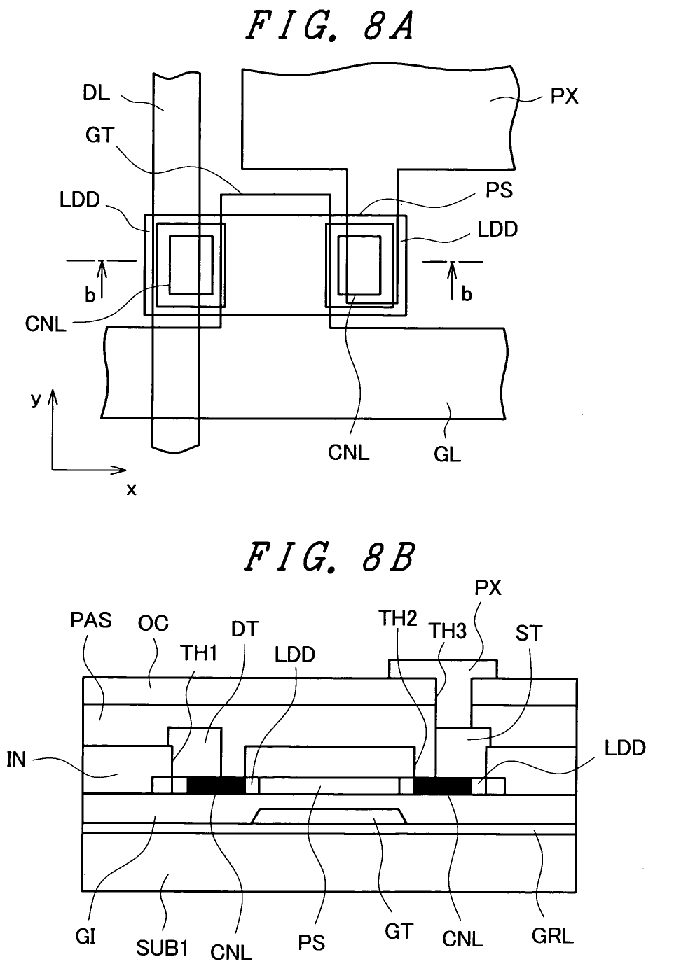

FIG. 8A is a schematic plan view showing yet another embodiment of a pixel of a display device according to the invention, corresponding to FIG. 6A. FIG. 8B is a cross sectional view along the line b-b in FIG. 8A, corresponding to FIG. 6B.

FIG. 8A is similar to FIG. 6A in that an annular LDD layer LDD is formed around a contact layer CNL at both ends of a semiconductor layer PS in a thin film transistor TFT.

Whereas, FIG. 8A is different from FIG. 6A in that a drain electrode DT (drain signal line DL) is formed so as to avoid the connection with the LDD layer LDD on the channel region side, and that a source electrode ST is formed so as to avoid the connection with the LDD layer LDD on the channel region side.

This configuration can avoid the flowing of off current to the drain electrode DT, the LDD layer LDD on the channel region side, the channel region, the LDD layer LDD on the channel region side, and the source electrode ST, for example, in the configuration shown in FIG. 6.

A manufacturing method of the display device having the configuration described above can apply the manufacturing method shown in FIG. 7, in which only the pattern of the drain signal line DL (drain electrode DT) and the source electrode ST is different upon forming them.

In the above-described embodiments, each of the LDD layers LDD is formed on the drain electrode side and the source electrode side. However, it is apparent that the LDD layer LDD may be formed on one of the electrode sides.

Further, in any of the above-described embodiments, the n-type thin film transistor is shown. However, it is apparent that the thin film transistor may be of the p-type.

Each of the above-described embodiments may be used alone or in combination. An effect of each of the embodiments can be provided alone or synergistically.

What is claimed is:

1. A display device comprising a thin film transistor above a substrate, wherein
the thin film transistor is configured to include a gate electrode, a gate insulating film formed to cover the gate electrode, a semiconductor layer formed to stride over the gate electrode on the gate insulating film, an inter-layer insulating film formed to cover the semiconductor layer, and a pair of electrodes formed to be connected to each of sides of the semiconductor layer interposing the gate electrode therebetween through contact holes formed through the inter-layer insulating film,
the semiconductor layer has a first layer, second layers, and a third layer,
a part of the first layer is a channel region of the thin film transistor,
the second layers are impurity layers formed at each connecting portion of the pair of electrodes,
the third layer is an impurity layer whose impurity concentration is lower than that of the second layer, and
the third layer is annularly formed to surround the second layer formed at the connecting portion of at least one of the pair of electrodes.

2. The display device according to claim 1, wherein a region surrounding the third layer is the first layer as viewed in a plane.

3. The display device according to claim 1, wherein an edge portion on the channel region side of the thin film transistor among edge portions of the third layer is in contact with the first layer as viewed in a plane, and
edge portions other than the edge portion on the channel region side of the thin film transistor among edge portions surrounding the third layer is in contact with the inter-layer insulating film as viewed in a plane.

4. The display device according to claim 1, wherein a region surrounding the third layer is the first layer as viewed in a plane, and
the entire area of the third layer is formed at the connecting portion.

5. The display device according to claim 1, wherein a region surrounding the third layer is the first layer as viewed in a plane,
the third layer has a first region formed in contact with the electrode and a second region formed in contact with the inter-layer insulating film on an upper layer of the third layer, and
an edge portion on the channel region side of the thin film transistor among edge portions of the third layer is the second region.

6. The display device according to claim 1, wherein the semiconductor layer is formed of polysilicon.

7. A method for manufacturing a display device comprising the steps of:
forming, above a substrate, a gate electrode, a gate insulating film formed to cover the gate electrode, a semiconductor layer formed to stride over the gate electrode on the gate insulating film, and an inter-layer insulating film formed to cover the semiconductor layer;
forming a resist film having an opening at a predetermined portion on the inter-layer insulating film,
forming a contact hole exposing a part of the semiconductor layer through the inter-layer insulating film by etching using the resist film as a mask;
making the opening of the resist film larger than the contact hole;
implanting a high-concentration impurity into the semiconductor layer through the contact hole;
implanting a low-concentration impurity having the same conductivity type as the high-concentration impurity through the inter-layer insulating film around the contact hole; and
removing the resist film to form an electrode connected to the semiconductor layer through the contact hole.

8. The method for manufacturing a display device according to claim 7, wherein the step of making the opening of the resist film larger than the contact hole includes the step of drawing back the resist film around the opening by ashing.

9. The method for manufacturing a display device according to claim 7, wherein the resist film has a region around the opening whose thickness is less than that of the resist film in other region, and
the step of making the opening of the resist film larger than the contact hole includes the step of removing the region whose thickness is less than that of the resist film in other region.

10. The method for manufacturing a display device according to claim 7, wherein the semiconductor layer is formed of polysilicon.

11. A method for manufacturing a display device comprising the steps of:
forming, above a substrate, a gate electrode, a gate insulating film formed to cover the gate electrode, a semiconductor layer formed to stride over the gate electrode on the gate insulating film, and an inter-layer insulating film formed to cover the semiconductor layer;
forming a resist film having an opening at a predetermined portion on the inter-layer insulating film;
forming a contact hole exposing a part of the semiconductor layer larger than the opening of the resist film through the inter-layer insulating film by etching using the resist film as a mask;
implanting a high-concentration impurity into the semiconductor layer through the opening of the resist film;
removing the resist film and implanting a low-concentration impurity having the same conductivity type as the high-concentration impurity into the semiconductor layer through the contact hole; and
forming an electrode connected to the semiconductor layer through the contact hole.

12. The method for manufacturing a display device according to claim 11, wherein the semiconductor layer is formed of polysilicon.
